(19) United States
(12) Patent Application Publication
(10) Pub. No.: US 2005/0184407 A1
(43) Pub. Date: Aug. 25, 2005

(54) Transistor circuit, thin film transistor circuit and display device

(76) Inventor: Takahiro Korenari, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/059,441

(22) Filed: Feb. 17, 2005

(30) Foreign Application Priority Data
Feb. 20, 2004 (JP) 2004-044361

(51) Int. Cl. G02F 1/13; H01L 21/00; H01L 51/20

(52) U.S. Cl. 257/E51.005; 349/2

(57) ABSTRACT

A TFT circuit includes a source terminal, a drain terminal, and first and second transistors having source-drain paths that are connected in series between the source terminal and the drain terminal, and mutually independent gate electrodes. The TFT circuit further includes upper and lower shaping circuits that, at least, turn off all of the first and second transistors by differentiating gate potentials such that a voltage between the source terminal and the drain terminal may substantially equally be distributed to the first and second transistors.

### CROSS-REFERENCE TO RELATED APPLICATIONS

This application is based upon and claims the benefit of priority from prior Japanese Patent Application No. 2004-044361, filed Feb. 20, 2004, the entire contents of which are incorporated herein by reference.

### BACKGROUND OF THE INVENTION

1. Field of the Invention

The present invention relates to a transistor circuit that is formed by using thin film transistors in principle, a thin film transistor circuit and a display device that incorporates the transistor or thin film transistor circuit.

2. Description of the Related Art

A thin film transistor (TFT) is a MOS (MIS) field effect transistor that is formed in a semiconductor film deposited on an insulation substrate. In this description, a field effect transistor, which is formed in a semiconductor wafer that is attached to an insulation substrate to constitute an SOI (Semiconductor On Insulator) substrate, is similarly treated as a thin film transistor. The source-drain breakdown voltage (SD breakdown voltage) of the thin film transistor is generally low. An increase in off-leak current or a latch-up phenomenon occurs at a relatively low source-drain voltage. In the latch-up phenomenon, ionization of semiconductor becomes a trigger to continuously feed current to a pn junction that is parasitic on a semiconductor thin film, leading to device destruction. Thus, the thin film transistor is not suited to a use that requires a high SD breakdown voltage.

In recent years, a liquid crystal display device of a type having a built-in drive circuit has been developed. In this liquid crystal display device, a plurality of display pixels are formed in a display panel, along with the drive circuit for driving the display pixels. The drive circuit includes a logic circuit section that processes a video signal with a low power source voltage of about 3.3 V, and an output circuit section that drives the display pixels with a high power source voltage of about ±5 V in accordance with a processing result of the logic circuit section. In this case, an SD breakdown voltage of about 4 V to 6 V is needed for the transistors for the logic circuit section, and an SD breakdown voltage of about 10 V to 12 V is needed for the transistors for the output circuit section and pixel switches. It is preferable in terms of manufacturing cost to form the transistors for the output circuit section and pixel switches and the transistors for the logic circuit section at the same time by a common manufacturing process (see, e.g. Jpn. Pat. Appln. KOKAI Publication No. 2000-353947).

In the prior art, a multi-gate transistor is used to improve the SD breakdown voltage of a single-gate transistor. The multi-gate transistor has a multi-gate structure wherein a plurality of gate electrodes are arranged over a semiconductor film that is covered with an insulation film, and are electrically interconnected. The multi-gate structure is electrically equivalent to a circuit wherein source-drain paths of single-gate transistors are connected in series and gate electrodes of these single-gate transistors are interconnected (see, e.g. Jpn. Pat. Appln. KOKAI Publication No. 2001-339044 and OKI Technical Review January 2003/Issue 193, Vol. 70, No. 1). In general, a double-gate transistor with two arranged gate electrodes is used as a transistor for the output circuit section and for the pixel switch.

FIG. 22 shows a relationship of potentials which are set in order to turn on the double-gate transistor. As is shown in FIG. 22, in the case where a source potential is GND (=0 V) and the double-gate transistor is turned on by an over-drive scheme in which a gate potential Vg is set to be greater than a drain potential VDD (=10 V), the source-drain voltage is substantially equally distributed to first and second transistors 1 and 2 that constitute the double-gate transistor. Thereby, the SD breakdown voltage of the double-gate transistor becomes about double the SD breakdown voltage of the single transistor. In short, the SD breakdown voltage of the multi-gate transistor increases in proportion to the number of transistors.

FIG. 23 shows a relationship of potentials which are set in order to turn off the double-gate transistor. If the gate potential Vg is lowered to 0 V that is equal to the source potential GND and the double-gate transistor is turned off, most of the source-drain voltage (=VDD) is distributed to the second one of the transistors. Consequently, in the OFF-state, a remarkable increase in SD breakdown voltage cannot be expected. In other words, the multi-gate structure is very effective in the case where the SD breakdown voltage in the ON-state (conductive state) is required, but not effective in the case where the SD breakdown voltage in the OFF-state (non-conductive state) is required. Further, for the above-described reason, it is also difficult to increase the SD breakdown voltage in the OFF-state in the circuit wherein the source-drain paths of the single-gate transistors are connected in series and the gate electrodes of these single-gate transistors are interconnected.

### BRIEF SUMMARY OF THE INVENTION

The object of the present invention is to provide a transistor circuit, a thin film transistor circuit, and a display device, wherein an SD breakdown voltage can be increased at least in an OFF-state.

According to a first aspect of the present invention, there is provided a transistor circuit comprising: source and drain terminals; a plurality of transistors having source-drain paths that are connected in series between the source terminal and the drain terminal, and mutually independent gate electrodes; and control means for, at least, turning off all of the transistors by substantially equalizing potential differences between the gate electrodes such that a voltage between the source terminal and the drain terminal is substantially equally distributed to the transistors.

According to a second aspect of the present invention, there is provided a thin film transistor circuit comprising: source and drain terminals; a plurality of thin film transistors having source-drain paths that are connected in series between the source terminal and the drain terminal, and mutually independent gate electrodes; and control means for, at least, turning off all of the thin film transistors by substantially equalizing potential differences between the gate electrodes such that a voltage between the source terminal and the drain terminal is substantially equally distributed to the thin film transistors.

According to a third aspect of the present invention, there is provided a display device comprising: a plurality of display pixels; a plurality of scan lines that are arranged along the rows of display pixels; a plurality of data lines that are arranged along the columns of display pixels; and a plurality of pixel switches that are arranged near intersections of the scan lines and the data lines, respectively, and each of which electrically connects an associated one of the data lines to an associated one of the display pixels under control of an associated one of the scan lines, wherein at least the pixel switch includes a transistor circuit that includes: source and drain terminals; a plurality of transistors having source-drain paths that are connected in series between the source terminal and the drain terminal, and mutually independent gate electrodes; and control means for, at least, turning off all of the transistors by substantially equalizing potential differences between the gate electrodes such that a voltage between the source terminal and the drain terminal is substantially equally distributed to the transistors.

According to a fourth aspect of the present invention, there is provided a display device comprising: a plurality of display pixels; a plurality of scan lines that are arranged along the rows of display pixels; a plurality of data lines that are arranged along the columns of display pixels; and a plurality of pixel switches that are arranged near intersections of the scan lines and the data lines, respectively, and each of which electrically connects an associated one of the data lines to an associated one of the display pixels under control of an associated one of the scan lines, wherein at least the pixel switch includes a thin film transistor circuit that includes: source and drain terminals; a plurality of thin film transistors having source-drain paths that are connected in series between the source terminal and the drain terminal, and mutually independent gate electrodes; and control means for, at least, turning off all of the thin film transistors by substantially equalizing potential differences between the gate electrodes such that a voltage between the source terminal and the drain terminal is substantially equally distributed to the thin film transistors.

In the transistor circuit, the thin film transistor circuit and the display device, as a gate control of setting the transistors into the OFF-state, substantially equal potential differences are set between the gate electrodes of these transistors. Thus, the voltage between the source and drain is substantially equally distributed to the plural transistors. In this case, the SD breakdown voltage in the OFF-state of each transistor can be increased in proportion to the number of transistors.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate an embodiment of the invention, and together with the general description given above and the detailed description of the embodiment given below, serve to explain the principles of the invention.

FIG. 1 schematically shows the circuit configuration of a liquid crystal display device according to an embodiment of the present invention;

FIG. 2 shows the schematic cross-sectional structure of the liquid crystal display device shown in FIG. 1;

FIG. 3 shows a thin film transistor (TFT) circuit that constitutes a pixel switch shown in FIG. 1;

FIG. 4 shows the plan-view structure of a double-gate transistor shown in FIG. 3;

FIG. 5 shows the cross-sectional structure of the double-gate transistor shown in FIG. 3;

FIG. 6 is a view for explaining the operation of a clip circuit shown in FIG. 3;

FIG. 7 shows amplitudes of gate pulses that are supplied to first and second gate electrodes shown in FIG. 3;

FIG. 8 shows gate pulses that are supplied to the first and second gate electrodes shown in FIG. 3 in the ON-state;

FIG. 9 shows gate pulses that are supplied to the first and second gate electrodes shown in FIG. 3 in the OFF-state;

FIG. 10 is a graph showing the relationship between the drain voltage and drain current of the double-gate transistor shown in FIG. 3 with respect to various gate potentials;

FIG. 11 shows a first modification of the TFT circuit shown in FIG. 3;

FIG. 12 shows a logic circuit section in a scan line driver shown in FIG. 1;

FIG. 13 shows an output circuit section in the scan line driver shown in FIG. 1;

FIG. 14 shows the circuit configuration of a CMOS inverter circuit shown in FIG. 13;

FIG. 15 shows a modification of the CMOS inverter circuit shown in FIG. 14;

FIG. 16 shows an example in which the TFT circuit with the structure shown in FIG. 3 is incorporated in a transfer gate that constitutes an analog switch;

FIG. 17 shows an example of a charge-pump-type voltage-doubler circuit that is applicable to a level shifter shown in FIG. 13;

FIG. 18 shows a second modification of the TFT circuit shown in FIG. 3;

FIG. 19 shows a plan-view structure of a triple-gate transistor shown in FIG. 18;

FIG. 20 shows the cross-sectional structure of the triple-gate transistor shown in FIG. 18;

FIG. 21 shows amplitudes of gate pulses that are supplied to first and second gate electrodes shown in FIG. 18;

FIG. 22 shows a relationship of potentials which are set in order to turn on a double-gate transistor in the prior art;

FIG. 23 shows a relationship of potentials which are set in order to turn off a double-gate transistor in the prior art; and

FIG. 24 is a view showing a laser crystallization apparatus for recrystallizing a non-single crystal semiconductor film into a single crystal semiconductor film used to form thin film transistors.

### DETAILED DESCRIPTION OF THE INVENTION

A liquid crystal display device according to an embodiment of the present invention will now be described with reference to the accompanying drawings.

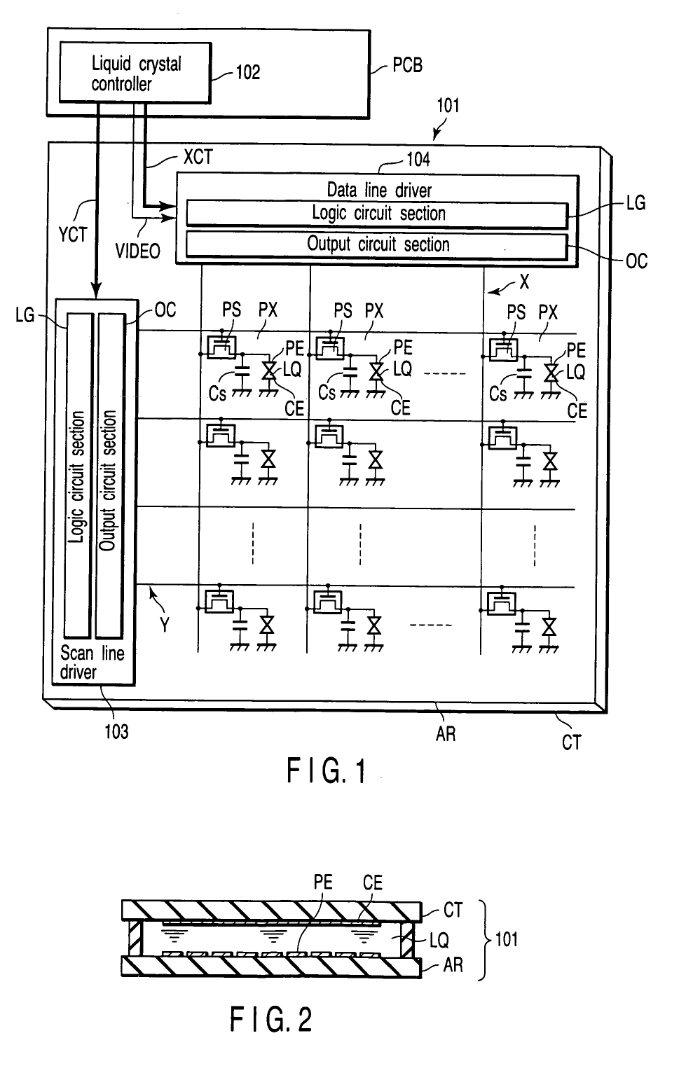

FIG. 1 schematically shows the circuit configuration of this liquid crystal display device, and FIG. 2 shows the schematic cross-sectional structure of the liquid crystal display device.

The liquid crystal display device comprises a liquid crystal display panel 101 and a liquid crystal controller 102 for controlling the liquid crystal display panel 101. The liquid crystal display panel 101 is configured, for example, such that a liquid crystal layer LQ is held between an array substrate AR and a counter substrate CT. The liquid crystal controller 102 is disposed on a drive circuit board PCB that is independent from the liquid crystal display panel 101.

The liquid crystal display panel 101 includes a plurality of display pixels PX that are arranged in a matrix; a plurality of scan lines Y that are arranged along the rows of display pixels PX; a plurality of data lines X that are arranged along the columns of display pixels PX; a plurality of pixel switches PS which are disposed near intersections between the data lines X and scan lines Y and each of which captures a data signal from the associated data line X in response to a gate pulse from the associated scan line Y to supply the data signal to the associated display pixel PX; a scan line driver 103 that drives the scan lines Y; and a data line driver 104 that drives the data lines X. The scan lines Y, data lines X, pixel switches PX, scan line driver 103 and data line driver 104 are formed on the array substrate AR. Each of the display pixels PX comprises one of pixel electrodes PE that are formed on the array substrate AR; a single common electrode CE that is formed on the counter substrate CT so as to face the pixel electrodes PE and is set at a common potential; a part of the liquid crystal layer LQ which is located between the pixel electrode and the common electrode CE; and a storage capacitance Cs that is formed on the array substrate AR and connected in parallel to a liquid crystal capacitance between the pixel electrode PE and common electrode CE. The storage capacitance Cs holds a voltage of a data signal that is supplied from the pixel switch PS, and applies the voltage of the data signal to the pixel electrode PE. The transmittance of the display pixel PX is controlled by a potential difference between the pixel electrode PE and the common electrode CE.

The liquid crystal controller 102 receives a digital video signal VIDEO and a sync signal, which are supplied, for example, from outside, and generates a vertical scan control signal YCT and a horizontal scan control signal XCT. The vertical scan control signal YCT is fed to the scan line driver 103, and the horizontal scan control signal XCT is fed to the data line driver 104 along with the video signal VIDEO. The scan line driver 103 is controlled by the vertical scan control signal YCT and successively supplies a gate pulse to the plural scan lines Y in a single vertical scan (frame) period. The gate pulse is supplied to the associated scan line Y for only a single horizontal scan period (1 H). The data line driver 104 is controlled by the horizontal scan control signal XCT. The data line driver 104 executes serial-parallel conversion and digital-analog conversion of video signals VIDEO that are input during a horizontal scan period in which one scan line Y is driven by the gate pulse, and supplies data signals for one row to the plural data lines X. Each of the scan line driver 103 and data line driver 104 includes a logic circuit section LG that operates with a relatively low power source voltage, and an output circuit section OC that operates with a power source voltage higher than the power source voltage of the logic circuit section LG.

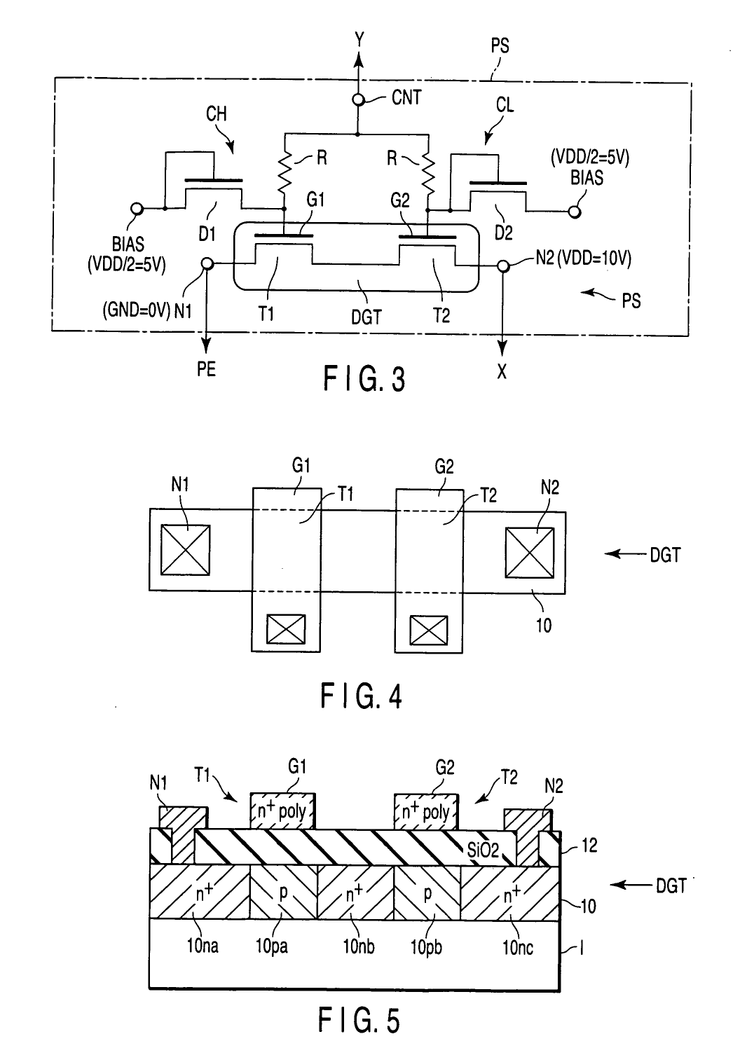

FIG. 3 shows a thin film transistor (TFT) circuit that has an SOI structure and constitutes the pixel switch PS shown in FIG. 1. FIG. 4 shows the plan-view structure of a double-gate transistor DGT shown in FIG. 3, and FIG. 5 shows the cross-sectional structure of the double-gate transistor DGT shown in FIG. 3. In FIG. 5, the double-gate transistor DGT is formed in a crystallized semiconductor thin film provided and crystallized on an insulation substrate I, such as a glass substrate. The TFT circuit comprises a source terminal N1, a drain terminal N2, a double-gate transistor DGT, an upper clip circuit CH and a lower clip circuit CL. The source terminal N1 is connected to the pixel electrode PE, and the drain terminal N2 is a drain electrode of the double-gate transistor DGT, which is connected to the data line X. The upper clip circuit CH determines the upper limit of the potential range of the input signal, and the lower clip circuit CL determines the lower limit of the potential range of the input signal.

The double-gate transistor DGT includes, for example, a polysilicon semiconductor film 10, a gate insulation film 12 that covers the polysilicon semiconductor film 10, and a first gate electrode G1 and a second gate electrode G2, which are disposed in parallel on the gate insulation film 12 between the source terminal N1 and drain terminal N2. The polysilicon semiconductor film 10 includes n⁺ impurity regions 10na, 10nb and 10nc, and p-type impurity regions 10pa and 10pb. The gate electrode G1, p-type impurity region 10pa and n⁺ impurity regions 10na and 10nb constitute a single-gate thin film transistor T1, and the gate electrode G2, p-type impurity region 10pb and n⁺ impurity regions 10nb and 10nc constitute a single-gate thin film transistor T2. The n⁺ impurity regions 10na and 10nb are disposed on both sides of the gate electrode G1 as source and drain regions of the thin film transistor T1. The n⁺ impurity regions 10nb and 10nc are disposed on both sides of the gate electrode G2 as source and drain regions of the thin film transistor T2. The p-type impurity regions 10pa and 10pb are disposed below the gate electrodes G1 and G2 as channel regions of the thin film transistors T1 and T2. The gate electrodes Gl and G2 are formed of n⁺ polysilicon that is doped with n-type impurities so as to have low resistance. The source terminal N1 is a source electrode of the double-gate transistor DGT, which is connected to the n⁺ impurity region 10na via a contact hole formed in the gate insulation film 12. The drain terminal N2 is a drain electrode of the double-gate transistor DGT, which is connected to the n⁺ impurity region 10nc via a contact hole formed in the gate insulation film 12. The gate electrode G1 is disposed on the source terminal N1 side, and the gate electrode G2 is disposed at a greater distance from the source terminal N1 than the gate electrode G1. In this double-gate transistor DGT, the n⁺ impurity region 10nb serves both as the drain region of the N-channel thin film transistor T1 and as the source region of the N-channel thin film transistor T2. Alternatively, the double-gate transistor DGT, for example, may be replaced with two single-gate N-channel thin film transistors, whose source-drain current paths are connected in series by wiring.

The upper clip circuit CH includes a resistor R that is connected between a control input terminal CNT and the first gate electrode G1, and an N-channel thin film transistor D1 that has a source-drain path connected between the first gate electrode G1 and a bias power terminal BIAS and a gate electrode connected to the bias power terminal BIAS. The lower clip circuit CL includes a resistor R that is connected between the control input terminal CNT and the second gate electrode G2, and an N-channel thin film transistor D2 that has a source-drain path connected between the second gate electrode G2 and the bias power terminal BIAS and a gate electrode connected to the second gate electrode G2. The thin film transistor D1 and thin film transistor D2 are used as diodes having different bias directions.

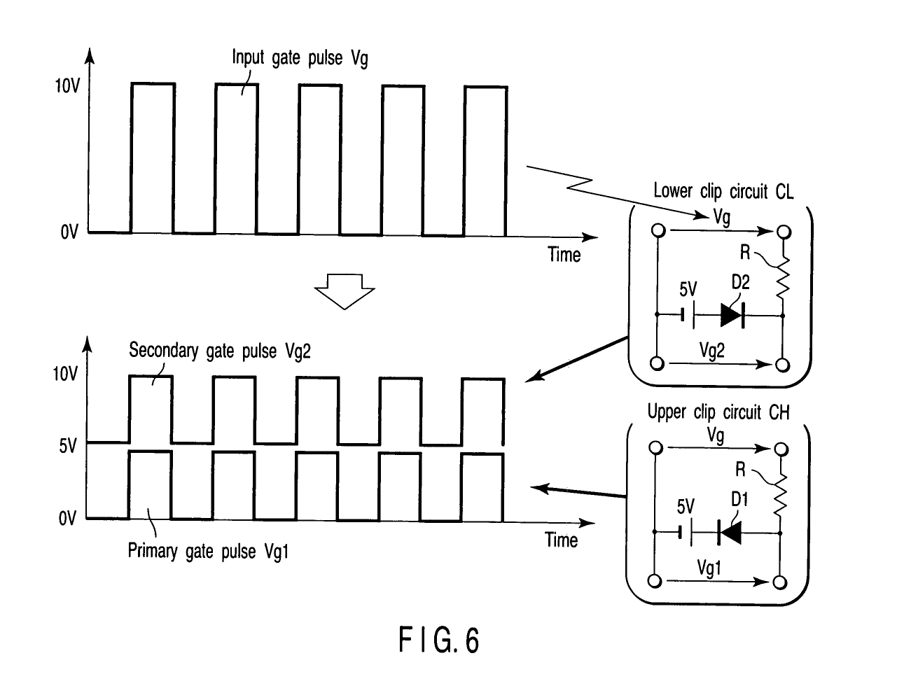

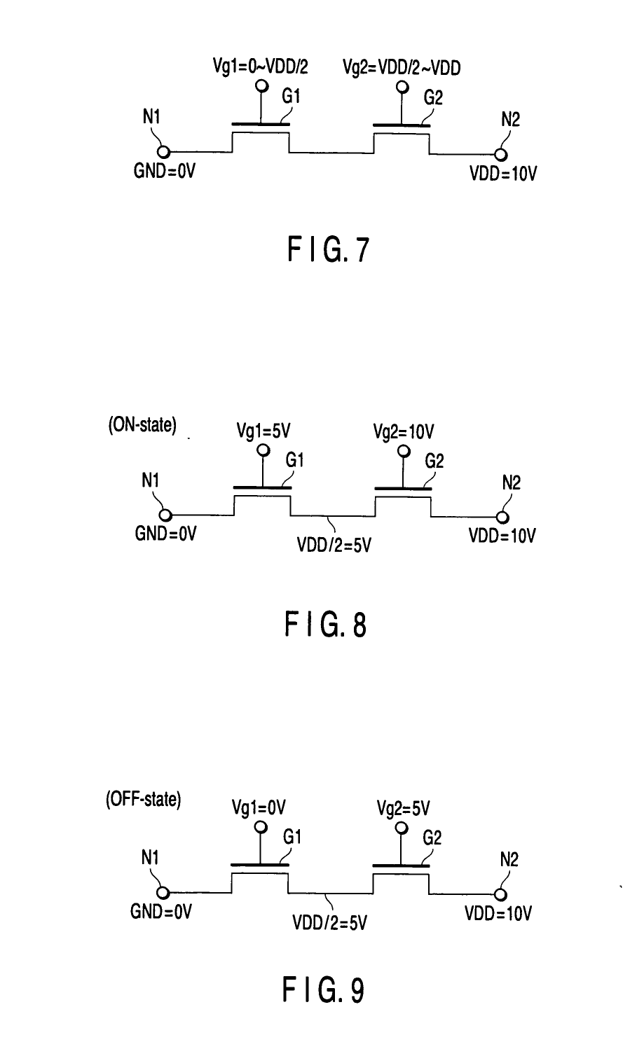

In the TFT circuit shown in FIG. 3, the voltage between the source terminal N1 and drain terminal N2 varies depending on the amplitude of the data signal that is supplied from the data line X. This voltage takes a maximum value when there is a relationship in relative potential between a potential GND=0 V of the source terminal N1 and a potential VDD=10 V of the drain terminal N2. In this case, as shown in FIG. 6, a gate pulse Vg is set at 0 V that is equal to the potential GND of the source terminal N1, when the double-gate transistor DGT is set in the OFF-state (non-conductive state). The gate pulse Vg is set at 10 V that is equal to the potential VDD of the drain terminal N2, when the double-gate transistor DGT is set in the ON-state (conductive state). The upper clip circuit CH and lower clip circuit CL constitute a shaping circuit that shapes the gate pulse Vg in a range between 0 V and VDD (=10 V), which is supplied from the control input terminal CNT, into a primary gate pulse Vg1 for the first gate electrode G1 and a secondary gate pulse Vg2 for the second gate electrode G2, which have the same amplitude but have different potential ranges. The potential of the bias power terminal BIAS is set at VDD/2=5 V. Thus, as shown in FIG. 6, the upper clip circuit CH supplies the shaped pulse in a range between 0 V and 5 V to the first gate electrode Gl as the primary gate pulse Vg1. The lower clip circuit CL supplies the shaped pulse in a range between 5 V and 10 V to the second gate electrode G2 as the secondary gate pulse Vg2. FIG. 7 shows the amplitudes of the primary gate pulse Vg1 and secondary gate pulse Vg2 in a generalized fashion. The amplitude of the primary gate pulse Vg1 is set in a range of 0 to VDD/2, and the amplitude of the secondary gate pulse Vg2 is set in a range of VDD/2 to VDD.

When the double-gate transistor DGT is to be set in the ON-state (conductive state), the upper clip circuit CH and lower clip circuit CL shape the gate pulse Vg of 10 V, as described above, and supply the primary gate pulse Vg1 of VDD/2=5 V and the secondary gate pulse Vg2 of VDD=10 V to the gate electrode G1 and gate electrode G2, respectively, as illustrated in FIG. 8. As a result, the voltage (=10 V) between the source terminal N1 and drain terminal N2 is substantially equally distributed to the thin film transistors T1 and T2 of the double-gate transistor DGT, and a node potential between the thin film transistors T1 and T2 is set at VDD/2 (=5 V). Thereby, the SD breakdown voltage of the double-gate transistor DGT in the ON-state is increased to about double the SD breakdown voltage of a single transistor.

When the double-gate transistor DGT is to be set in the OFF-state (non-conductive state), the upper clip circuit CH and lower clip circuit CL shape the gate pulse Vg of 0 V, as described above, and supply the primary gate pulse Vg1 of 0 V and the secondary gate pulse Vg2 of VDD/2=5 V to the gate electrode G1 and gate electrode G2, respectively, as illustrated in FIG. 9. Consequently, the voltage (=10 V) between the source terminal N1 and drain terminal N2 is substantially equally distributed to the thin film transistors T1 and T2 of the double-gate transistor DGT, and a node potential between the thin film transistors T1 and T2 is set at VDD/2 (=5 V). Thereby, the SD breakdown voltage of the double-gate transistor DGT in the OFF-state is increased to about double the SD breakdown voltage of a single transistor.

In the above-described TFT circuit, the shaping circuit employing the upper clip circuit CH and lower clip circuit CL serve as control means that turns on and off both the thin film transistors T1 and T2 by differentiating the potentials of the gate electrodes G1 and G2 such that the voltage between the source terminal N1 and drain terminal N2 may substantially equally be distributed to the thin film transistors T1 and T2 of the double-gate transistor DGT. Specifically, the potentials of the gate electrodes G1 and G2 are set at 0 V and 5 V in the OFF-state and at 5 V and 10 V in the ON-state. In short, the gate electrodes G1 and G2 are set at potentials that successively increase with a substantially constant potential difference from the source terminal N1 side to the drain terminal N2 side.

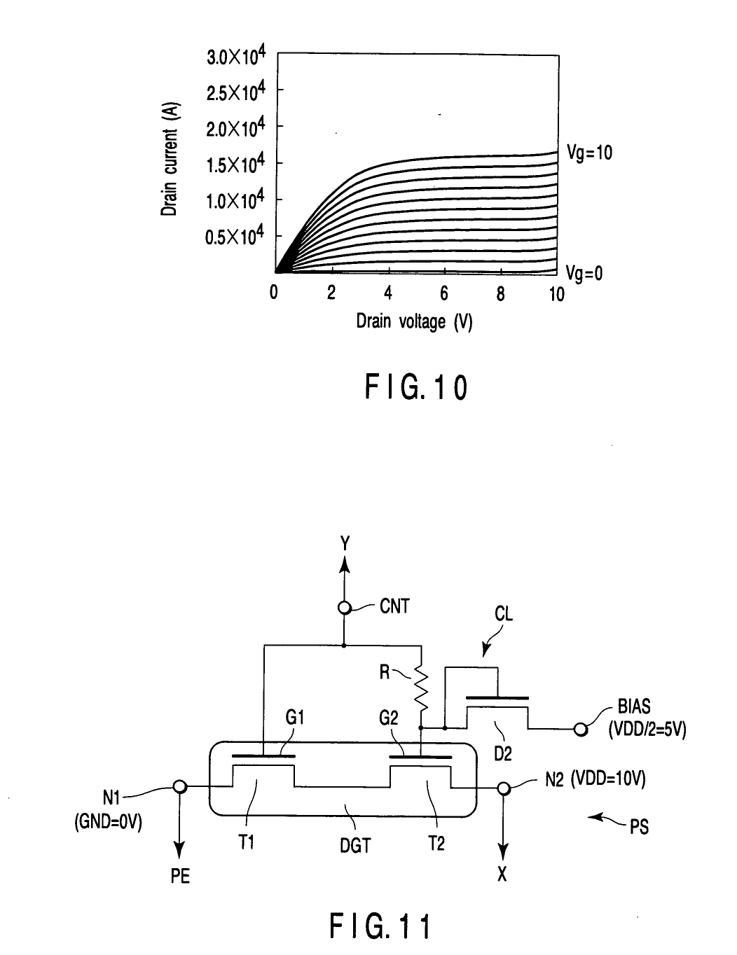

FIG. 10 shows the relationship between the drain voltage and drain current of the double-gate transistor DGT with respect to various gate potentials. Since the voltage between the source terminal N1 and drain terminal N2 is substantially equally distributed to the thin film transistors T1 and T2, the linearity of the characteristic curves with Vg=0 V (OFF-state) and Vg=10 V (ON-state) is substantially maintained even when the drain voltage is VDD=10 V. Therefore, it is confirmed from FIG. 10 that the SD breakdown voltage of at least 10 V is obtained both in the ON-state and OFF-state.

In this TFT circuit, the following setting is executed: Vg1=0 to VDD/2, and Vg2=VDD/2 to VDD. The term VDD/2 is used in order to maximize the SD breakdown voltage. In a case where the SD breakdown voltage may somewhat be sacrificed, the off-leak current can be reduced by setting a decreased value as the term VDD/2. On the other hand, the ON-current can be increased by setting an increased value as the term VDD/2. It is preferable to adjust the term VDD/2 in consideration of the necessity of these points.

In a case where the ON-current is still deficient by the above-described adjustment, it is possible to supply a gate pulse Vg=15 V, which exceeds the drain potential VDD=10 V, to the control input terminal CNT in order to over-drive the double-gate transistor DGT. In this case, the above-described shaping circuit is so configured as to shape the gate pulse Vg and to supply, e.g. the primary gate pulse Vg1=10 V and the secondary gate pulse Vg2=15 V to the gate electrodes G1 and G2.

The TFT circuit shown in FIG. 3 aims at improving the SD breakdown voltage in the OFF-state and ON-state. If it should suffice to improve the SD breakdown voltage in the OFF-state alone, the upper clip circuit CH shown in FIG. 3 may be dispensed with, and a TFT circuit with a modified structure as shown in FIG. 11 may be adopted.

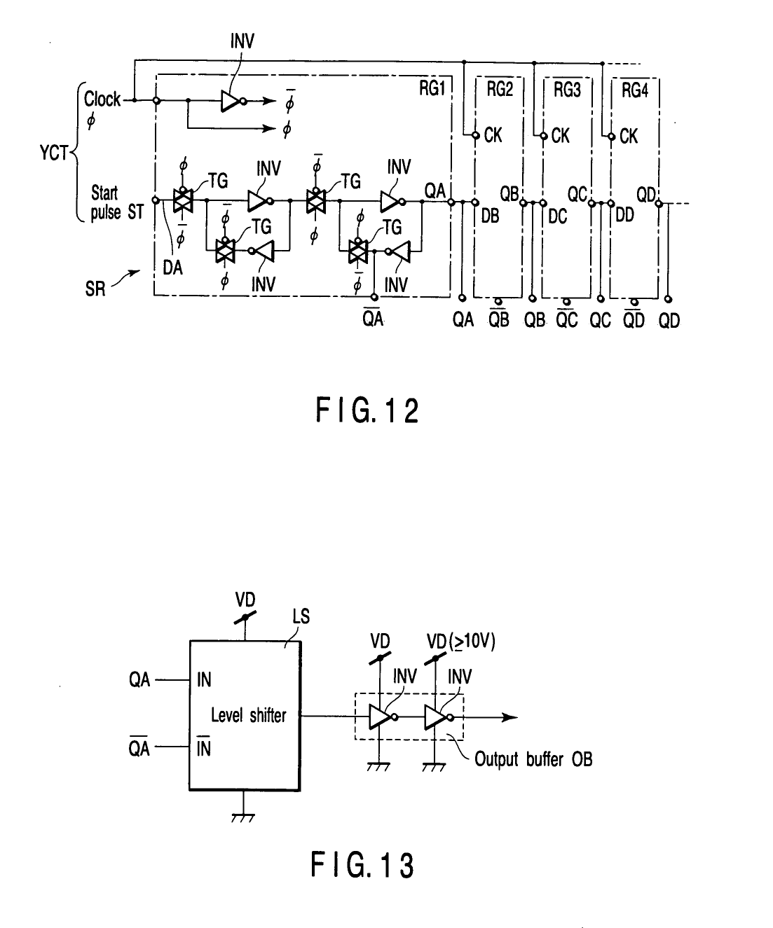

FIG. 12 shows the logic circuit section LG in the scan line driver 103 shown in FIG. 1. The logic circuit section LG includes a shift register SR that shifts a start pulse ST in sync with a clock φ. The shift register SR comprises a plurality of register units RG1, RG2, RG3, . . . , connected in series. Each of the register units RG1, RG2, RG3, . . . , is a combination of CMOS inverter circuits INV and CMOS transfer gates TG. The shift register unit RG1, RG2, RG3, . . . , holds the start pulse ST that is shifted in synchrony with the clock pulse, and successively outputs the shifted start pulse ST from a non-inversion output terminal QA, QB, QC, QD, . . . , and an inversion output terminal/QA, /QB, /QC, /QD, . . . .

FIG. 13 shows the output circuit section OC in the scan line driver 103 shown in FIG. 1. The output circuit section OC includes a level shifter LS that increases the amplitude of the output signal, and an output buffer OB that shapes the waveform of the output signal. Each of the level shifter LS and output buffer OB is a combination of CMOS inverter circuits INV. The CMOS inverter circuit INV in the output circuit OC, however, is designed to operate at a power source voltage VD (≧10 V) that is higher than the power source voltage for the CMOS inverter circuit INV in the logic circuit section LG.

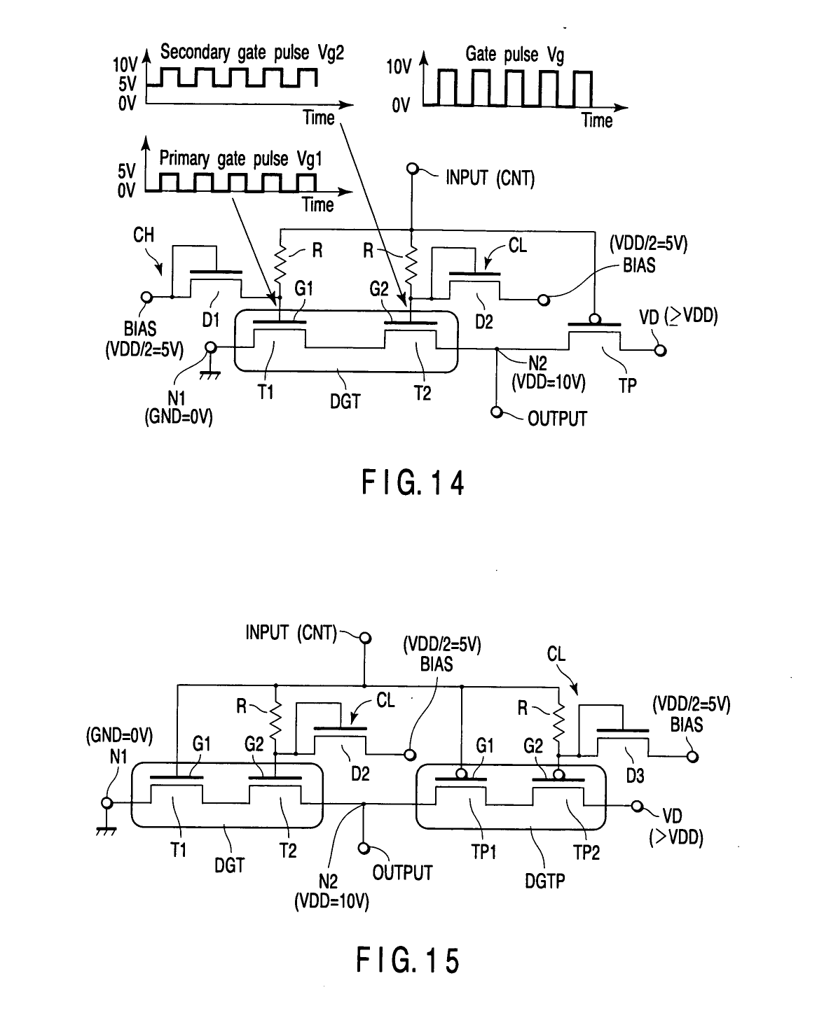

FIG. 14 shows the circuit configuration of the CMOS inverter circuit INV shown in FIG. 13. The CMOS inverter circuit INV includes a P-channel thin film transistor TP in addition to a TFT circuit that has the same structure as the TFT circuit shown in FIG. 3. The gate electrode of the thin film transistor TP is connected to the control input terminal CNT, and the source-drain path of the thin film transistor TP is connected between a power terminal VD and an output terminal OUTPUT. In addition, the output terminal OUTPUT is connected to a ground terminal via the source-drain path of the double-gate transistor DGT.

In the CMOS inverter circuit INV shown in FIG. 14, the voltage between the source terminal N1 and drain terminal N2 of the double-gate transistor DGT varies depending on the amplitude of the gate pulse Vg that is supplied from the level shifter LS. This voltage takes a maximum value when there is a relationship in relative potential between a potential GND=0 V of the source terminal N1 and a potential VDD=10 V of the drain terminal N2. In this case, the gate pulse Vg is set at 0 V that is equal to the potential GND of the source terminal N1 in order to turn off the double-gate transistor DGT and to turn on the transistor TP. On the other hand, the gate pulse Vg is set at 10 V that is equal to the potential VDD of the drain terminal N2 in order to turn on the double-gate transistor DGT and to turn off the transistor TP. The upper clip circuit CH and lower clip circuit CL constitute a shaping circuit that shapes the gate pulse Vg in a range between 0 V and VDD (=10 V), which is supplied from the control input terminal CNT, into a primary gate pulse Vg1 for the first gate electrode G1 and a secondary gate pulse Vg2 for the second gate electrode G2, which have the same amplitude but have different potential ranges. The upper clip circuit CH supplies the shaped pulse in a range between 0 V and 5 V to the first gate electrode G1 as the primary gate pulse Vg1. The lower clip circuit CL supplies the shaped pulse in a range between 5 V and 10 V to the second gate electrode G2 as the secondary gate pulse Vg2. If the amplitudes of the primary gate pulse Vg1 and secondary gate pulse Vg2 are generalized in the same manner as the TFT circuit shown in FIG. 3, the amplitude of the primary gate pulse Vg1 is set in a range of 0 to VDD/2 and the amplitude of the secondary gate pulse Vg2 is set in a range of VDD/2 to VDD. Thereby, the SD breakdown voltage in the ON-state and OFF-state is improved in the CMOS inverter circuit INV, and the CMOS inverter circuit INV is made operable in a power supply system having about double the SD breakdown voltage of the single-gate transistor.

As regards the CMOS inverter circuit INV shown in FIG. 14, too, in a case where the SD breakdown voltage may somewhat be sacrificed, the off-leak current can be reduced by setting a decreased value as the term VDD/2. On the other hand, the ON-current can be increased by setting an increased value as the term VDD/2. It is preferable to adjust the term VDD/2 in consideration of the necessity of these points.

In general, the CMOS inverter circuit needs to have an OFF-state breakdown voltage. Thus, the upper clip circuit CH of the CMOS inverter circuit INV shown in FIG. 14 may be dispensed with, and the CMOS inverter circuit INV may be modified as shown in FIG. 15. In this modification, the thin film transistor TP shown in FIG. 14 is replaced with a TFT circuit that comprises a double-gate transistor DGTP and a lower clip circuit CL that is added to the double-gate transistor DGTP. In this case, the P-channel double-gate transistor DGTP is configured such that source-drain paths of two P-channel single-gate thin film transistors TP1 and TP2 are connected in series. With this structure, a problem of deficiency in SD breakdown voltage of the P-channel thin film transistor TP can be solved.

In this embodiment, a substantially constant potential difference is set between the respective gate electrodes as a gate control voltage for setting the double-gate transistor DGT or DGTP in the non-conductive state. For example, in the gate of the double-gate transistor DGT, the gate electrodes G1 and G2 are set at different potentials Vg1 and Vg2, and thus the voltage between the source terminal N1 and drain terminal N2 is substantially equally distributed to the thin film transistors T1 and T2. Since the source-drain voltage is set for each of the thin film transistors T1 and T2 in this manner, the SD breakdown voltage in the OFF-state can be substantially doubled in proportion to the number of transistors T1 and T2.

The TFT circuit with the structure shown in FIG. 3 is applicable to various circuit components that require at least an OFF-state SD breakdown voltage.

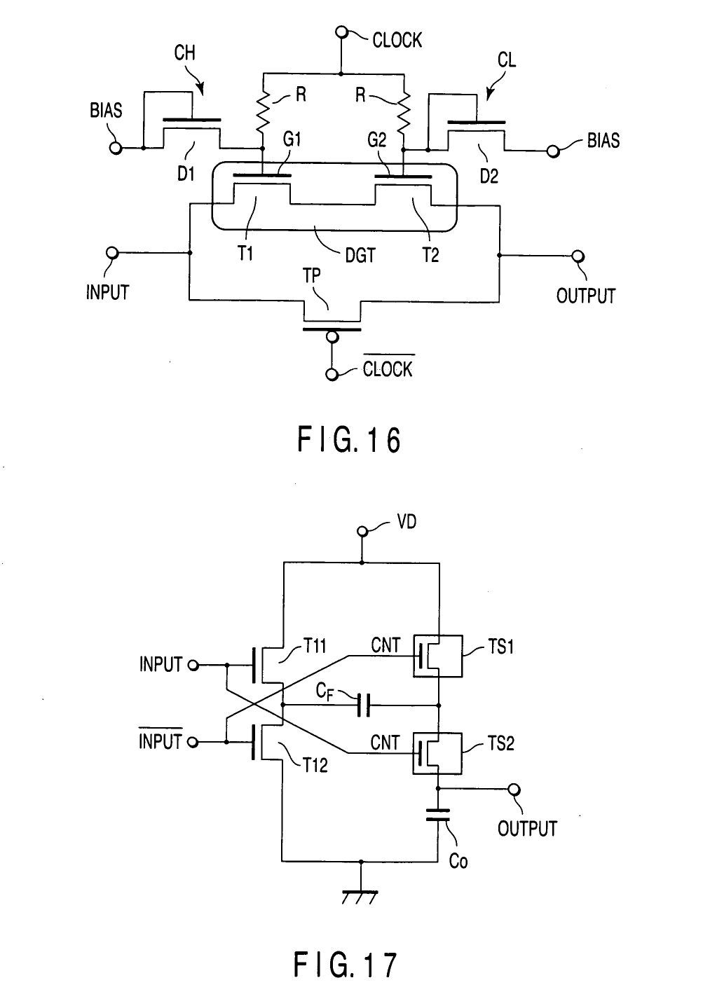

FIG. 16 shows an example in which the TFT circuit is incorporated in a transfer gate that constitutes an analog switch. In this case, a source-drain path of a P-channel thin film transistor TP and a source-drain path of a double-gate transistor DGT are connected in parallel between an input terminal INPUT and an output terminal OUTPUT. A non-inversion clock terminal CLOCK (CNT) is connected to a first gate electrode G1 and a second gate electrode G2 of a double-gate transistor DGT via an upper clip circuit CH and a lower clip circuit CL. An inversion clock terminal /CLOCK is connected to the gate electrode of the P-channel thin film transistor TP.

The double-gate transistor DGT is configured such that the source-drain paths of two N-channel single-gate thin film transistors T1 and T2 are connected in series. Since the upper clip circuit CH and lower clip circuit CL apply the above-mentioned potential differences to the gate electrodes G1 and G2, the SD breakdown voltage of the double-gate transistor DGT can be improved both in the ON-state and OFF-state.

This transfer gate is usable, for example, as the transfer gate TG that constitutes the shift register SR shown in FIG. 12. Since the shift register SR is a part of the logic circuit section LC, it does not require a high SD breakdown voltage. On the other hand, in the data line driver 104, a transfer gate with a high SD breakdown voltage is required since the output circuit section OC selectively outputs a data signal.

FIG. 17 shows an example of a charge-pump-type voltage-doubler circuit that is applicable to the level shifter LS shown in FIG. 13. The voltage-doubler circuit comprises N-channel thin film transistors T11 and T12, TFT circuits TS1 and TS2, and capacitors C_{F} and C_{O}. A non-inversion input terminal INPUT and an inversion input terminal /INPUT are connected to the transistors T11 and T12. A source-drain path of the transistor T11 is connected between a power terminal VD and one end of the capacitor C_{F}. A source-drain path of the transistor T12 is connected between the above-mentioned one end of the capacitor C_{F} and a ground terminal. The inversion input terminal/INPUT and non-inversion input terminal INPUT are connected to control input terminals CNT of the TFT circuits TS1 and TS2, respectively. Each of the TFT circuits TS1 and TS2 has the same structure as the TFT circuit shown in FIG. 3. The source-drain path of the double-gate transistor DGT of the TFT circuit TS1 is connected between the power terminal VD and the other end of the capacitor C_{F}. The source-drain path of the double-gate transistor DGT of the TFT circuit TS2 is connected between the other end of the capacitor C_{F} and an output terminal OUTPUT. The capacitor C_{O} is connected between the output terminal OUTPUT and the ground terminal.

In this voltage-doubler circuit, the output-side TFT circuit TS1, TS2 requires double the SD breakdown voltage of the input-side transistor T11, T12. The TFT circuit TS1, TS2 can meet this requirement since it comprises the double-gate transistor DGT, the gate potentials of which are controlled in the above-described manner.

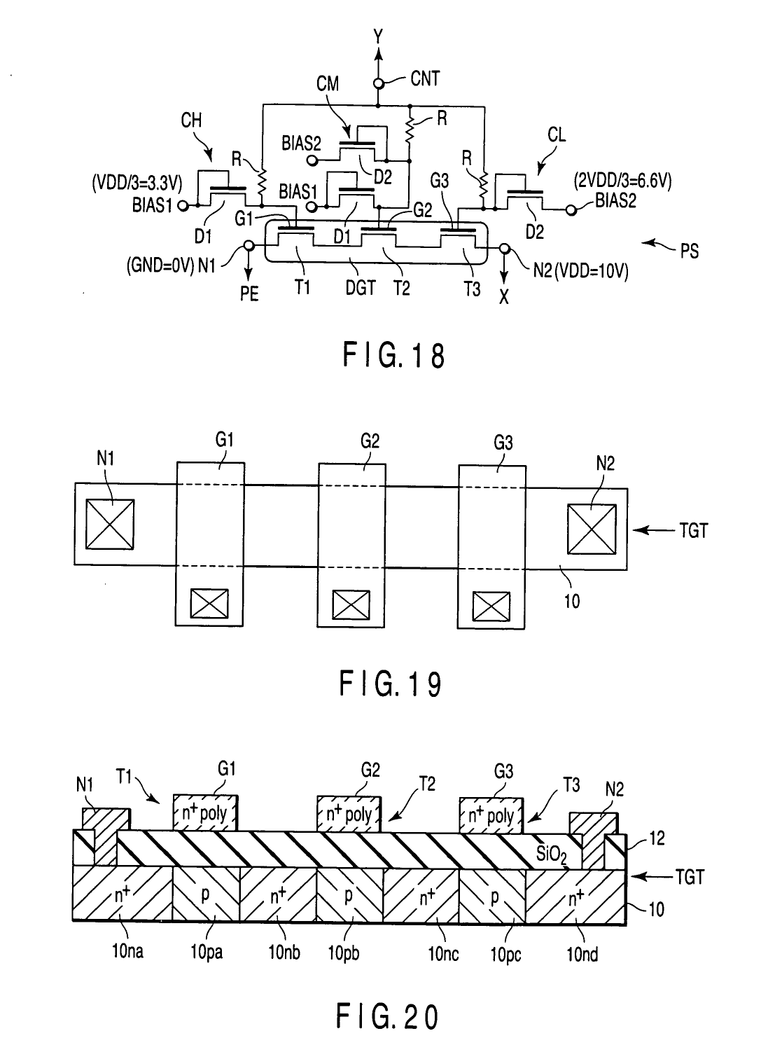

FIG. 18 shows a modification of the TFT circuit shown in FIG. 3. FIG. 19 shows the plan-view structure of a triple-gate transistor TGT shown in FIG. 18. FIG. 20 shows a cross-sectional structure of the triple-gate transistor TGT shown in FIG. 18. The TFT circuit comprises a source terminal N1, a drain terminal N2, a triple-gate transistor TGT, an upper clip circuit CH, a both-side clip circuit CM and a lower clip circuit CL. The source terminal N1 is connected to the pixel electrode PE, and the drain terminal N2 is a drain electrode of the triple-gate transistor TGT, which is connected to the data line X. The upper clip circuit CH determines the upper limit of the potential range of the input signal, the both-side clip circuit CM determines the upper and lower limits of the potential range of the input signal, and the lower clip circuit CL determines the lower limit of the potential range of the input signal.

The triple-gate transistor TGT includes, for example, a polysilicon semiconductor film 10, a gate insulation film 12 that covers the polysilicon semiconductor film 10, and first, second and third gate electrodes G1, G2 and G3, which are disposed in parallel on the gate insulation film 12 between the source terminal N1 and drain terminal N2. The polysilicon semiconductor film 10 includes n⁺ impurity regions 10na, 10nb, 10nc and 10ndand p-type impurity regions 10pa, 10pb and 10pc. The gate electrode G1, p-type impurity region 10pa and n⁺ impurity regions 10na and 10nb constitute a single-gate thin film transistor T1. The gate electrode G2, p-type impurity region 10pb and n⁺ impurity regions 10nb and 10nc constitute a single-gate thin film transistor T2. The gate electrode G3, p-type impurity region 10pc and n⁺ impurity regions 10nc and 10nd constitute a single-gate thin film transistor T3. The n⁺ impurity regions 10na and 10nb are disposed on both sides of the gate electrode G1 as source and drain regions of the thin film transistor T1. The n⁺ impurity regions 10nb and 10nc are disposed on both sides of the gate electrode G2 as source and drain regions of the thin film transistor T2. The n⁺ impurity regions 10nc and 10nd are disposed on both sides of the gate electrode G3 as source and drain regions of the thin film transistor T3. The p-type impurity regions 10pa, 10pb and 10pc are disposed below the gate electrodes G1, G2 and G3 as channel regions of the thin film transistors T1, T2 and T3. The gate electrodes G1, G2 and G3 are formed of n⁺ polysilicon that is doped with n-type impurities so as to have low resistance. The source terminal N1 is a source electrode of the triple-gate transistor TGT, which is connected to the n⁺ impurity region 10na via a contact hole formed in the gate insulation film 12. The drain terminal N2 is a drain electrode of the triple-gate transistor TGT, which is connected to the n⁺ impurity region 10nd via a contact hole formed in the gate insulation film 12. The gate electrode G1 is disposed on the source terminal N1 side, and the gate electrode G2 is disposed at a greater distance from the source terminal N1 than the gate electrode G1. The gate electrode G3 is disposed at a further distance from the source terminal N1 than the gate electrode G2. In this triple-gate transistor TGT, the n⁺ impurity region 10nb serves both as the drain region of the N-channel thin film transistor T1 and as the source region of the N-channel thin film transistor T2. The n⁺ impurity region 10nc serves both as the drain region of the N-channel thin film transistor T2 and as the source region of the N-channel thin film transistor T3. Alternatively, the triple-gate transistor TGT, for example, may be replaced with three single-gate N-channel thin film transistors, whose source-drain current paths are connected in series by wiring.

The upper clip circuit CH includes a resistor R that is connected between a control input terminal CNT and the first gate electrode G1, and an N-channel thin film transistor D1 that has a source-drain path connected between the first gate electrode G1 and a bias power terminal BIAS1 and a gate electrode connected to the bias power terminal BIAS1. The both-side clip circuit CM includes a resistor R that is connected between the control input terminal CNT and the second gate electrode G2, a thin film transistor D1 that has a source-drain path connected between the second gate electrode G2 and the bias power terminal BIAS1 and a gate electrode connected to the bias power terminal BIAS1, and an N-channel thin film transistor D2 that has a source-drain path connected between the second gate electrode G2 and the bias power terminal BIAS2 and a gate electrode connected to the second gate electrode G2. The lower clip circuit CL includes a resistor R that is connected between the control input terminal CNT and the third gate electrode G3, and an N-channel thin film transistor D2 that has a source-drain path connected between the third gate electrode G3 and the bias power terminal BIAS2 and a gate electrode connected to the third gate electrode G3. The thin film transistor D1 and thin film transistor D2 are used as diodes having different bias directions.

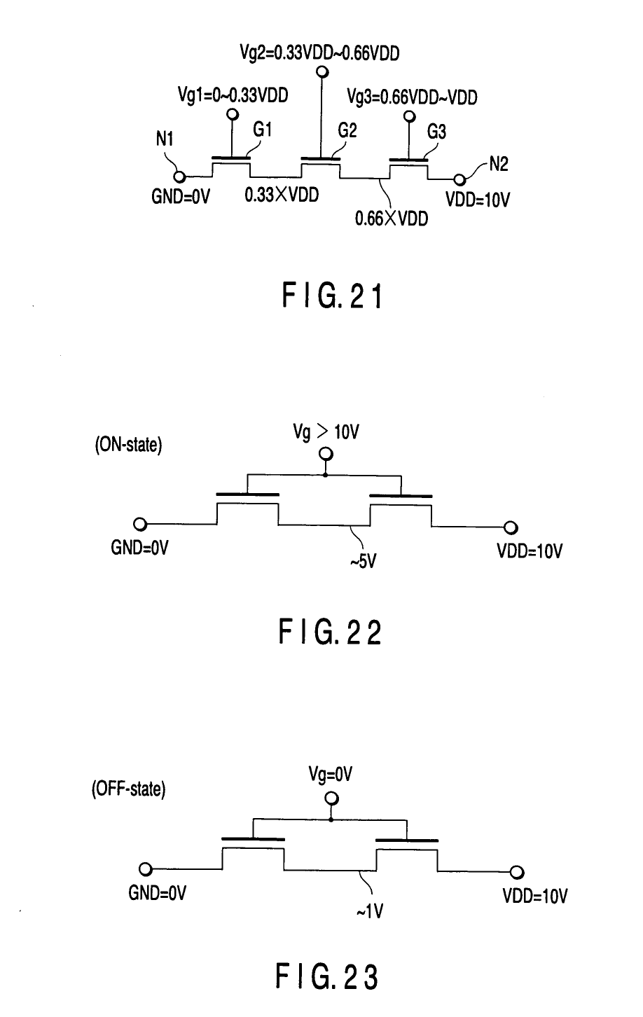

In the TFT circuit shown in FIG. 18, a gate pulse Vg is set at 0 V that is equal to the potential GND of the source terminal N1 in order to turn off the triple-gate transistor TGT. The gate pulse Vg is set at 10 V that is equal to the potential VDD of the drain terminal N2 in order to turn on the triple-gate transistor TGT. The upper clip circuit CH, both-side clip circuit CM and lower clip circuit CL constitute a shaping circuit that shapes the gate pulse Vg in a range between 0 V and VDD (=10 V), which is supplied from the control input terminal CNT, into a first gate pulse Vg1 for the first gate electrode G1, a second gate pulse Vg2 and a third gate pulse Vg3, which have the same amplitude but have different potential ranges. The potential of the bias power terminal BIAS1 is set at VDD/3=3.3 V, and the potential of the bias power terminal BIAS2 is set at 2VDD/3=6.6 V. Thus, as shown in FIG. 21, the upper clip circuit CH supplies the shaped pulse in a range between 0 V and 0.33 VDD to the first gate electrode G1 as the gate pulse Vg1. The both-side clip circuit CM supplies the shaped pulse in a range between 0.33 VDD and 0.66 VDD to the second gate electrode G2 as the gate pulse Vg2. The lower clip circuit CL supplies the shaped pulse in a range between 0.66 VDD and VDD to the third gate electrode G3 as the secondary gate pulse Vg3. In more detail, the amplitude of the gate pulse Vg1 is set in a range of 0 to VDD/3, the amplitude of the gate pulse Vg2 is set in a range of VDD/3 to 2VDD/3, and the amplitude of the gate pulse Vg3 is set in a range of 2VDD/3 to VDD.

When the triple-gate transistor is to be set in the ON-state, the upper clip circuit CH, both-side clip circuit CM and lower clip circuit CL shape the gate pulse Vg of 10 V and supply the gate pulse Vg1 of VDD/3=3.3 V, the gate pulse Vg2 of 2VDD/3=6.6 V and the gate pulse Vg3 of VDD=10 V to the gate electrode G1, gate electrode G2 and gate electrode G3, respectively. As a result, the voltage (=10 V) between the source terminal N1 and drain terminal N2 is substantially equally distributed to the thin film transistors T1, T2 and T3 of the triple-gate transistor TGT, and a node potential between the thin film transistors T1 and T2 is set at VDD/3 (=3.3 V) and a node potential between the thin film transistors T2 and T3 is set at 2VDD/3 (=6.6 V). Thereby, the SD breakdown voltage of the triple-gate transistor TGT in the ON-state is increased to about three times higher than the SD breakdown voltage of a single transistor.

When the triple-gate transistor is to be set in the OFF-state, the upper clip circuit CH, both-side clip circuit CM and lower clip circuit CL shape the gate pulse Vg of 0 V and supply the gate pulse Vg1 of 0 V, the gate pulse Vg2 of VDD/3=3.3 V and the gate pulse Vg3 of 2VDD/3=6.6 V to the gate electrode G1, gate electrode G2 and gate electrode G3, respectively. As a result, the voltage (=10 V) between the source terminal N1 and drain terminal N2 is substantially equally distributed to the thin film transistors T1, T2 and T3 of the triple-gate transistor TGT, and a node potential between the thin film transistors T1 and T2 is set at VDD/3 (=3.3 V) and a node potential between the thin film transistors T2 and T3 is set at 2VDD/3 (=6.6 V). Thereby, the SD breakdown voltage of the triple-gate transistor TGT in the OFF-state is increased to about three times higher than the SD breakdown voltage of a single transistor.

In the TFT circuit according to the above-described modification, the shaping circuit employing the upper clip circuit CH, both-side clip circuit CM and lower clip circuit CL functions as control means that turns on and off the thin film transistors T1, T2 and T3 by substantially equalizing the potential differences between the gate electrodes G1, G2 and G3 such that the voltage between the source terminal N1 and drain terminal N2 may substantially equally be distributed to the thin film transistors T1, T2 and T3 that constitute the triple-gate transistor TGT. Specifically, the potentials of the gate electrodes G1, G2 and G3 are set at 0 V, 3.3 V and 6.6 V in the OFF-state and at 3.3 V, 6.6 V and 10 V in the ON-state. In short, the gate electrodes G1, G2 and G3 are set at potentials that successively increase with a constant potential difference from the source terminal N1 side to the drain terminal N2 side.

In this modification, the structure of the TFT circuit becomes more complex than that of the TFT circuit shown in FIG. 3, but the SD breakdown voltage in the ON-state and OFF-state can further be improved.

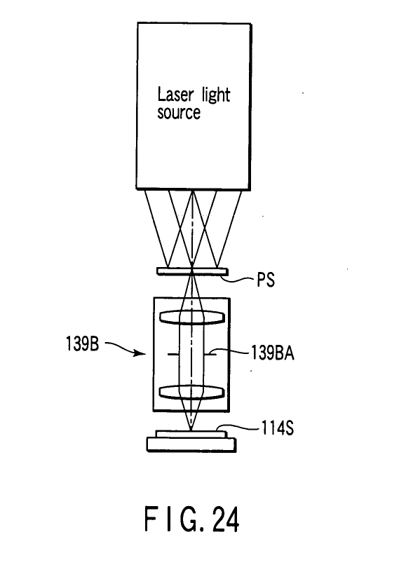

Further, the thin film transistors in the above-mentioned embodiment may be formed using a single crystal semiconductor film which is obtained as a result of recrystallization of a non-single crystal semiconductor film affected by a laser crystallization apparatus. This laser crystallization apparatus may have a structure shown in FIG. 24. In this apparatus, an optical imaging system 139B is disposed between a phase shifter PS and a thin film semiconductor substrate 114S to locate the phase shifter PS and thin film semiconductor substrate 114S at the optically conjugated positions. That is, the thin film semiconductor substrate 114S is set in a plane optically conjugated with the phase shifter PS (image plane of the optical imaging system 139B). An aperture diaphragm unit 139BA is disposed in an iris plane of the optical imaging system 139B. The aperture diaphragm unit 139BA includes a plurality of aperture diaphragms different from one another in the size of the aperture (light transmission portion), and these aperture diaphragms can be changed with respect to an optical path. Instead, the aperture diaphragm unit 139BA may be formed of an iris diaphragm with a continuously variable aperture. In any case, the size of the aperture of the aperture diaphragm unit 139BA (numerical aperture NA on the imaging side of the optical imaging system 139B) is set to obtain a required light intensity distribution of the inverse peak pattern on the semiconductor thin film 114 of the thin film semiconductor substrate 114S. In addition, the optical imaging system 139B may be a refractive optical system, reflective optical system, or a refractive and reflective optical system.

The present invention is applicable not only to the above-mentioned TFT circuits, but also to a transistor circuit that includes ordinary field effect transistors associated with each other to serve as a switch.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A transistor circuit comprising:
source and drain terminals;
a plurality of transistors having source-drain paths that are connected in series between the source terminal and the drain terminal, and mutually independent gate electrodes; and
control means for, at least, turning off all of the transistors by substantially equalizing potential differences between the gate electrodes such that a voltage between the source terminal and the drain terminal is substantially equally distributed to the transistors.

2. The transistor circuit according to claim 1, wherein the control means is configured to set potentials of the gate electrodes of the transistors at values that successively increase from the source terminal side toward the drain terminal side.

3. The transistor circuit according to claim 1, wherein the transistors are formed as a double-gate transistor having a first gate electrode that is disposed on the source terminal side, and a second gate electrode that is disposed at a greater distance from the source terminal than the first gate electrode.

4. The transistor circuit according to claim 3, wherein the control means is configured to set the first gate electrode at a first potential that is equal to a potential of the source terminal and to set the second gate electrode at a second potential that is higher than the first potential, thereby to turn off the double-gate transistor.

5. The transistor circuit according to claim 3, wherein the control means includes a shaping circuit that shapes an input signal in a range between a first potential, which is equal to a potential of the source terminal, and a second potential, which is equal to or higher than a potential of the drain terminal, and supplies the first gate electrode with a signal, which is shaped in a range between the first potential and ½ of the second potential, and the second gate electrode with a signal, which is shaped in a range between ½ of the second potential and the second potential.

6. The transistor circuit according to claim 1, wherein the transistors are formed as a triple-gate transistor having a first gate electrode that is disposed on the source terminal side, a second gate electrode that is disposed at a greater distance from the source terminal than the first gate electrode, and a third gate electrode that is disposed at a greater distance from the source terminal than the second gate electrode.

7. The transistor circuit according to claim 6, wherein the control means is configured to set the first gate electrode at a first potential that is equal to a potential of the source terminal, to set the second gate electrode at a second potential that is higher than the first potential, and to set the third gate electrode at a third potential that is higher than the second potential, thereby to turn off the triple-gate transistor.

8. The transistor circuit according to claim 6, wherein the control means includes a shaping circuit that shapes an input signal in a range between a first potential, which is equal to a potential of the source terminal, and a second potential, which is equal to or higher than a potential of the drain terminal, and supplies the first gate electrode with a signal, which is shaped in a range between the first potential and ⅓ of the second potential, the second gate electrode with a signal, which is shaped in a range between ⅓ of the second potential and ⅔ of the second potential, and the third gate electrode with a signal, which is shaped in a range between ⅔ of the second potential and the second potential.

9. The transistor circuit according to claim 5 or 8, wherein the shaping circuit comprises a clip circuit that limits a potential range of the input signal.

10. The transistor circuit according to claim 1, wherein the transistors are SOI transistors.

11. The transistor circuit according to claim 1, wherein the transistors are incorporated in an output circuit section of a display device.

12. The transistor circuit according to claim 1, wherein the transistors are incorporated in an inverter circuit.

13. A thin film transistor circuit comprising:
source and drain terminals;
a plurality of thin film transistors having source-drain paths that are connected in series between the source terminal and the drain terminal, and mutually independent gate electrodes; and
control means for, at least, turning off all of the thin film transistors by substantially equalizing potential differences between the gate electrodes such that a voltage between the source terminal and the drain terminal is substantially equally distributed to the thin film transistors.

14. A display device comprising:
a plurality of display pixels;
a plurality of scan lines that are arranged along the rows of display pixels;
a plurality of data lines that are arranged along the columns of display pixels; and
a plurality of pixel switches that are arranged near intersections of the scan lines and the data lines, respectively, and each of which electrically connects an associated one of the data lines to an associated one of the display pixels under control of an associated one of the scan lines,
wherein at least the pixel switch includes a transistor circuit that includes:
source and drain terminals;
a plurality of transistors having source-drain paths that are connected in series between the source terminal and the drain terminal, and mutually independent gate electrodes; and
control means for, at least, turning off all of the transistors by substantially equalizing potential differences between the gate electrodes such that a voltage between the source terminal and the drain terminal is substantially equally distributed to the transistors.

15. A display device comprising:
a plurality of display pixels;
a plurality of scan lines that are arranged along the rows of display pixels;
a plurality of data lines that are arranged along the columns of display pixels; and
a plurality of pixel switches that are arranged near intersections of the scan lines and the data lines, respectively, and each of which electrically connects an associated one of the data lines to an associated one of the display pixels under control of an associated one of the scan lines,
wherein at least the pixel switch includes a thin film transistor circuit that includes:
source and drain terminals;
a plurality of thin film transistors having source-drain paths that are connected in series between the source terminal and the drain terminal, and mutually independent gate electrodes; and
control means for, at least, turning off all of the thin film transistors by substantially equalizing potential differences between the gate electrodes such that a voltage between the source terminal and the drain terminal is substantially equally distributed to the thin film transistors.
